(19) United States
(12) Patent Application Publication
(10) Pub. No.: US 2015/0318112 A1
(43) Pub. Date: Nov. 5, 2015

(54) MULTILAYER CERAMIC ELECTRONIC COMPONENT AND BOARD HAVING THE SAME

(71) Applicant: SAMSUNG ELECTRO-MECHANICS CO., LTD., Suwon-si (KR)

(72) Inventors: Joon Hwan KWAG, Suwon-si (KR); Sang Hyuk KIM, Suwon-si (KR)

(21) Appl. No.: 14/561,202

(22) Filed: Dec. 4, 2014

(30) Foreign Application Priority Data
Apr. 30, 2014 (KR) 10-2014-0052535

(51) Int. Cl. H01G 4/30; H01G 4/012; H01G 4/12; H01C 7/00; H01F 27/28; H01L 41/083; H01C 7/10; H01G 4/248; H01G 2/06

(52) U.S. Cl. CPC H01G 4/30; H01G 4/248; H01G 4/012; H01G 4/1227; H01G 2/065; H01F 27/2804; H01L 41/083; H01C 7/10; H01C 7/008; H01F 2027/2809

(57) ABSTRACT

A multilayer ceramic electronic component may include: a ceramic body having first and second side surfaces opposing each other in a width direction, third and fourth end surfaces opposing each other in a length direction, and first and second main surfaces opposing each other in a thickness direction, and having a thickness larger than a width; internal electrodes disposed in the ceramic body; first and second external electrodes disposed on the third and fourth end surfaces of the ceramic body, respectively; and a support portion disposed on at least one of the first and second main surfaces and suppressing displacement of the ceramic body at the time of being mounted on a board.

### CROSS-REFERENCE TO RELATED APPLICATION

This application claims the benefit of Korean Patent Application No. 10-2014-0052535 filed on Apr. 30, 2014, with the Korean Intellectual Property Office, the disclosure of which is incorporated herein by reference.

### BACKGROUND

The present disclosure relates to a multilayer ceramic electronic component and a board having the same.

An electronic component using a ceramic material, such as a capacitor, an inductor, a piezoelectric element, a varistor, a thermistor, or the like, includes a ceramic body made of the ceramic material, internal electrodes formed in the ceramic body, and external electrodes formed on a surface of the ceramic body to be connected to the internal electrodes.

The multilayer ceramic electronic component may be mounted on a circuit board. In addition, when the multilayer ceramic electronic component is mounted on the circuit board, the multilayer ceramic electronic component may be electrically connected to a mounting pad on the circuit board through soldering, and the mounting pad may be connected to an external circuit through a wiring pattern or a conductive via of the board.

In the case in which the multilayer ceramic electronic component is misaligned at the time of being mounted on the circuit board, a mounting defect may occur, and short circuiting may occur due to a contact between the multilayer ceramic electronic component and an electronic component adjacent to the multilayer ceramic electronic component.

### Related Art Document

(Patent Document 1) Japanese Patent Laid-Open Publication No. 1997-260184

### SUMMARY

An exemplary embodiment in the present disclosure may provide a multilayer ceramic electronic component and a board having the same.

According to an exemplary embodiment in the present disclosure, a multilayer ceramic electronic component may include: a ceramic body including internal electrodes and dielectric layers; first and second external electrodes disposed on the ceramic body; and a support portion disposed on a main surface of the ceramic body.

A thickness of the ceramic body may be greater than a width thereof.

The support portion may be disposed between the first and second external electrodes to improve mounting stability of the multilayer ceramic electronic component.

According to an exemplary embodiment in the present disclosure, a board having a multilayer ceramic electronic component may include: a printed circuit board on which first and second electrode pads are formed; and the multilayer ceramic electronic component disposed on the printed circuit board, wherein the multilayer ceramic electronic component includes: a ceramic body; first and second external electrodes disposed on the ceramic body; and a support portion disposed on a main surface of the ceramic body.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a perspective view schematically showing a multilayer ceramic electronic component according to an exemplary embodiment of the present disclosure; FIG. 2 is a cross-sectional view taken along line A-A′ of FIG. 1;

FIG. 3 is a cross-sectional view taken along line B-B′ of FIG. 1;

FIG. 4 is a perspective view showing a modified example of the multilayer ceramic electronic component according to an exemplary embodiment of the present disclosure;

FIG. 5 is a perspective view showing a board having a multilayer ceramic electronic component according to another exemplary embodiment of the present disclosure; and

FIG. 6 is a cross-sectional view taken along line C-C′ of FIG. 5.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

### Multilayer Ceramic Electronic Component

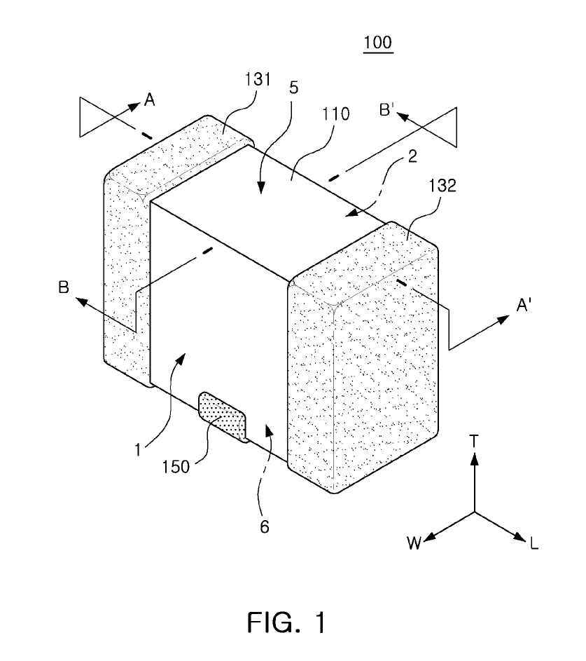

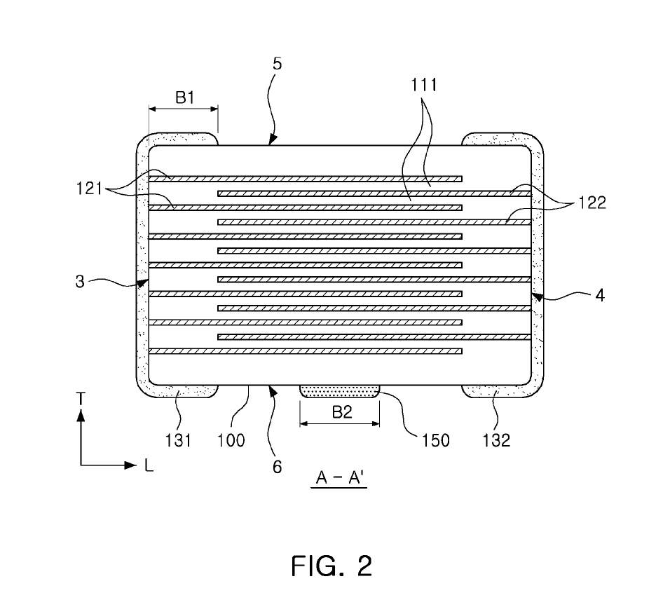

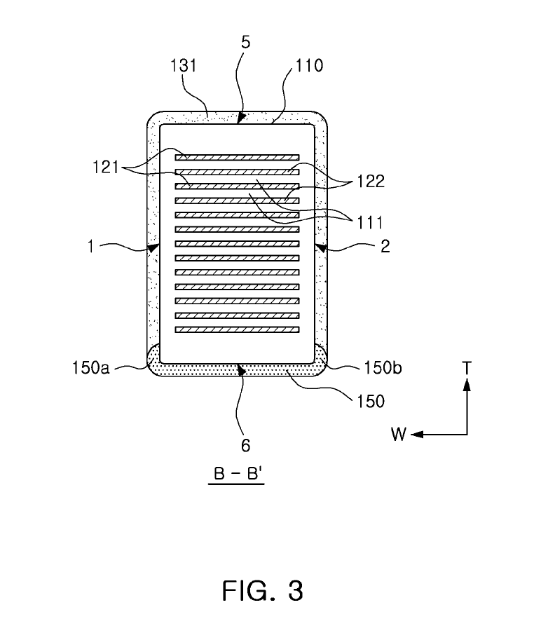

FIG. 1 is a perspective view schematically showing a multilayer ceramic electronic component 100 according to an exemplary embodiment of the present disclosure; FIG. 2 is a cross-sectional view taken along line A-A′ of FIG. 1; and FIG. 3 is a cross-sectional view taken along line B-B′ of FIG. 1.

Referring to FIGS. 1 and 2, the multilayer ceramic electronic component 100 according to this exemplary embodiment of the present disclosure may include a ceramic body 110, external electrodes 131 and 132, and a support portion 150.

The ceramic body 110 may include a plurality of dielectric layers 111 and have first and second side surfaces 1 and 2 opposing each other in a width direction, third and fourth end surfaces 3 and 4 opposing each other in a length direction, and first and second main surfaces 5 and 6 opposing each other in a thickness direction. A shape of the ceramic body 110 is not particularly limited. For example, the ceramic body 110 may have an approximate hexahedral shape even though it does not a hexahedral shape having complete straight lines.

According to the exemplary embodiment of the present disclosure, as shown in FIG. 1, a T-direction refers to a thickness direction of the ceramic body 110, an L-direction refers to a length direction of the ceramic body 110, and a W-direction refers to a width direction of the ceramic body 110.

The ceramic body 110 may include a plurality of dielectric layers 111 and internal electrodes 121 and 122. The ceramic body may include an active region in which the plurality of dielectric layers having the internal electrodes are stacked, and cover regions disposed above and below the active region.

The internal electrodes may include first and second internal electrodes 121 and 122. The first and second internal electrodes 121 and 122 may be alternately disposed on the dielectric layers, with at least one of the dielectric layers 111 interposed therebetween.

The first internal electrodes 121 may be exposed through the third side surface 3 of the ceramic body, and the second internal electrodes 122 may be exposed through the fourth side surface 4 of the ceramic body.

The cover regions may be disposed outside the outermost internal electrodes in order to protect the internal electrodes within the ceramic body from external impacts, and may be formed by stacking a single dielectric layer or two or more dielectric layers on the active region.

According to the exemplary embodiment of the present disclosure, as shown in FIG. 2, the dielectric layers 111 and the internal electrodes 121 and 122 may be stacked in the thickness direction of the ceramic body, but are not limited thereto.

As shown in FIG. 1, in the multilayer ceramic electronic component according to the exemplary embodiment of the present disclosure, a thickness T of the ceramic body is not substantially the same as a width W of the ceramic body, but may be larger than the width W of the ceramic body in order to obtain high capacitance.

According to the exemplary embodiment of the present disclosure, the first main surface 5 or the second main surface 6 of the ceramic body may be used as amounting surface adjacent to and facing a printed circuit board at the time of mounting the multilayer ceramic electronic component on the printed circuit board.

The multilayer ceramic electronic component 100 according to the exemplary embodiment of the present disclosure may obtain high capacitance by increasing the thickness of the ceramic body 110, without increasing a mounting area of the ceramic body 110 at the time of being mounted on the printed circuit board.

In the case in which the internal electrodes 121 and 122 are stacked in the thickness direction of the ceramic body 110 as shown in FIGS. 2 and 3 and the thickness of the ceramic body is increased, an increasing number of internal electrodes 121 and 122 may be stacked. Therefore, the capacitance of the multilayer ceramic electronic component may be increased even without increasing the mounting area occupied by the multilayer ceramic electronic component on the printed circuit board.

In the case in which the first and second internal electrodes 121 and 122 are stacked in the thickness direction of the ceramic body 110, they may be disposed horizontally with respect to the first main surface 5 or the second main surface 6 of the ceramic body. For example, the first and second internal electrodes 121 and 122 may be disposed horizontally to the mounting surface of the multilayer ceramic electronic component facing the printed circuit board, when the multilayer ceramic electronic component is mounted on the printed circuit board.

Although not shown, a direction in which the internal electrodes 121 and 122 and the dielectric layers 111 are stacked may be changed. For example, the internal electrodes 121 and 122 and the dielectric layers 111 may be stacked in the width direction of the ceramic body.

In the case in which the internal electrodes 121 and 122 are stacked in the width direction of the ceramic body 110 as in a modified exemplary embodiment of the present disclosure and the thickness of the ceramic body 110 is increased, an overlapping area of the internal electrodes 121 and 122 may be increased. In this case, higher capacitance may be secured even when the mounting area occupied by the multilayer ceramic electronic component according to the embodiment of the present disclosure is equal to that of the exiting multilayer ceramic electronic component. In addition, even when the number of stacked internal electrodes is not significantly increased, high capacitance may be secured due to an increase in the overlapping area of the internal electrodes. As compared with the case in which the internal electrodes are stacked in the thickness direction, the number of current paths is decreased, whereby an equivalent series inductance (ESL) may be reduced.

In the case in which the first and second internal electrodes 121 and 122 are stacked in the width direction of the ceramic body 110, they may be disposed vertically to the first main surface 5 or the second main surface 6 of the ceramic body. The first and second internal electrodes 121 and 122 may be disposed vertically to the mounting surface of the multilayer ceramic electronic component facing the printed circuit board, when the multilayer ceramic electronic component is mounted on the printed circuit board.

The ceramic body 110 may be formed by stacking and sintering the plurality of dielectric layers 111 and the internal electrodes 121 and 122, and a shape and a dimension of the ceramic body 110 and the number of stacked dielectric layers 111 are not limited to those shown in the accompanying drawings.

According to the exemplary embodiment of the present disclosure, an average thickness of the dielectric layers 111 may be arbitrarily changed in accordance with a target capacitance of the multilayer ceramic electronic component.

In addition, the dielectric layer 111 may contain a ceramic powder having high permittivity, such as a barium titanate (BaTiO₃) based powder or a strontium titanate (SrTiO₃) based powder. However, the present disclosure is not limited thereto.

A material forming the first and second internal electrodes 121 and 122 is not particularly limited, and for example, it may be a conductive paste including at least one of a noble metal material such as palladium (Pd), a palladium-silver (Pd—Ag) alloy, or the like, nickel (Ni), and copper (Cu).

Meanwhile, the first and second internal electrodes 121 and 122 may be formed by printing the conductive pastes containing a conductive metal on the dielectric layers 111 at a predetermined thickness.

The external electrodes 131 and 132 may be disposed on outer surfaces of the ceramic body 110 to be electrically connected to the internal electrodes 121 and 122. The external electrodes may include first and second external electrodes 131 and 132. The first external electrode 131 may be disposed on the third side surface 3 of the ceramic body 110 to be electrically connected to the first internal electrodes 121, and the second external electrode 132 may be disposed on the fourth side surface 4 of the ceramic body 110 to be electrically connected to the second internal electrodes 122.

The first and second external electrodes 131 and 132 may include band portions extended from the third and fourth end surfaces 3 and 4 to at least one of the first and second main surfaces 5 and 6 and the first and second side surfaces 1 and 2.

The first and second external electrodes 131 and 132 may be formed by applying a paste for external electrodes prepared by adding a glass frit to a metal powder to the outer surfaces of the ceramic body and then sintering the same, but are not limited thereto. A method of applying the paste for external electrodes may include a method of dipping the ceramic body in a conductive paste or a method of screen-printing the paste for external electrodes on the ceramic body, but is not limited thereto.

In the case in which the thickness of the ceramic body 110 is larger than the width thereof as in the exemplary embodiment of the present disclosure, higher capacitance may be secured even when the mounting area occupied by the multilayer ceramic electronic component according to the embodiment of the present disclosure is equal to that of the exiting multilayer ceramic electronic component. However, due to a rise in the center of gravity of the multilayer ceramic electronic component, a chip may be inclined in a taping pocket and not picked up during a pick-up process, and an occurrence frequency of a chip collapse phenomenon during a mounting process may be increased.

Particularly, when or after the multilayer ceramic electronic component is mounted on the printed circuit board, the multilayer ceramic electronic component may collapse or may be inclined or displaced, such that it contacts an electronic component disposed adjacently to the multilayer ceramic electronic component, thereby causing short-circuiting.

According to the exemplary embodiment of the present disclosure, the support portion 150 may be disposed on the mounting surface of the ceramic body 110 to solve the above-mentioned problems. As shown in FIGS. 1 through 3, the support portion 150 maybe disposed on at least one of the first and second main surfaces 5 and 6 of the ceramic body 110.

In the case in which the multilayer ceramic electronic component 100 is disposed on the printed circuit board by causing the first main surface 5 or the second main surface 6 of the ceramic body 110 on which the support portion 150 is disposed to be a bottom surface (the mounting surface), the support portion 150 may suppress the displacement of the multilayer ceramic electronic component. Here, the displacement of the multilayer ceramic electronic component means that the multilayer ceramic electronic component is inclined or collapses.

In the case in which the multilayer ceramic electronic component 100 is mounted on the printed circuit board by allowing the first main surface 5 or the second main surface 6 of the ceramic body 110 to be the mounting surface, the support portion 150 disposed on the mounting surface may suppress the displacement of the multilayer ceramic electronic component and improve mounting stability during the mounting process.

A function and a role of the support portion 150 may be different from those of the external electrodes 131 and 132. Therefore, the support portion 150 is not electrically connected to the internal electrodes 121 and 122 included in the multilayer ceramic electronic component, but may be electrically insulated from the internal electrodes 121 and 122.

The support portion 150 may be disposed between the first and second external electrodes 131 and 132 and may be disposed to be spaced from the first and second external electrodes 131 and 132.

When the multilayer ceramic electronic component is mounted on the printed circuit board, the support portion 150 may be connected to a dummy solder distinguished from a main solder disposed on the external electrodes. Here, a portion of the support portion 150 may be buried in the dummy solder to thereby fix the position of the multilayer ceramic electronic component.

Here, in the case in which the support portion 150 is not spaced from the first and second external electrodes 131 and 132, it may be not easy to fix the position of the multilayer ceramic electronic component 100 by using the dummy solder, and an electrical short-circuit may occur between the first and second external electrodes 131 and 132.

The first and second external electrodes 131 and 132 may include the band portions extended from the third and fourth end surfaces 3 and 4 of the ceramic body to the first and second main surfaces 5 and 6 of the ceramic body 110.

The band portions may further include portions of the first and second external electrodes extended to the first and second side surfaces 1 and 2 of the ceramic body.

According to the exemplary embodiment of the present disclosure, when a width of the band portion of the first or second external electrode is B1 and a width of the support portion 150 is B2 as shown in FIG. 2, 0.8≦B2/B1≦1.2 may be satisfied. In the case in which B2/B1 is less than 0.8, a ratio of the support portion 150 fixed by the dummy solder in the length direction of the ceramic body to an overall length of the ceramic body is significantly low, whereby it may not be easy to fix the position of the multilayer ceramic electronic component, in particular, it may be difficult to prevent the displacement of the multilayer ceramic electronic component at the time of being mounted on the printed circuit board. In the case in which B2/B1 exceeds 1.2, it may be difficult to cause the support portion 150 to be buried in the dummy solder, whereby it may not be easy to fix the position of the multilayer ceramic electronic component. In this case, in order to force the support portion 150 to be buried in the dummy solder, a large amount of dummy solder may be used, causing an electrical short circuiting with the first and second external electrodes 131 and 132.

The first and second external electrodes 131 and 132 may include the band portions extended from the third and fourth end surfaces 3 and 4 to the first and second main surfaces 5 and 6 and the first and second side surfaces 1 and 2.

The width B1 of the band portion of the external electrode refers to a width of a portion of the external electrode disposed on each of the first and second main surfaces 5 and 6, and the first and second side surfaces 1 and 2 of the ceramic body. That is, the width B1 of the band portion of the external electrode refers to a width of the portion of the first or second external electrode 131 or 132 extended from the third or fourth end surface 3 or 4 to the first or second main surface 5 or 6 or from the third or fourth end surface 3 or 4 to the first or second side surface 1 or 2, as shown in FIG. 2.

The support portion 150 may include extended portions 150a and 150b extended from the first or second main surface 5 or 6 of the ceramic body 110 to the first and second side surfaces 1 and 2 thereof. The extended portions 150a and 150b of the support portion 150 extended from the first or second main surface to the first and second side surfaces by a predetermined height may have an effect of increasing a width of a portion of the ceramic body 110 on which the support portion 150 is disposed. Therefore, the collapse or displacement of the multilayer ceramic electronic component 100 may be suppressed. In addition, in the case in which the support portion 150 includes the extended portions 150a and 150b, the dummy solder may be provided to enclose the extended portions 150a and 150b of the support portion 150 disposed at edges at which the first or second main surface 5 or 6 of the ceramic body meets the first and second side surfaces 1 and 2 of the ceramic body, whereby the displacement of the multilayer ceramic electronic component may be efficiently suppressed when the multilayer ceramic electronic component is mounted on the printed circuit board.

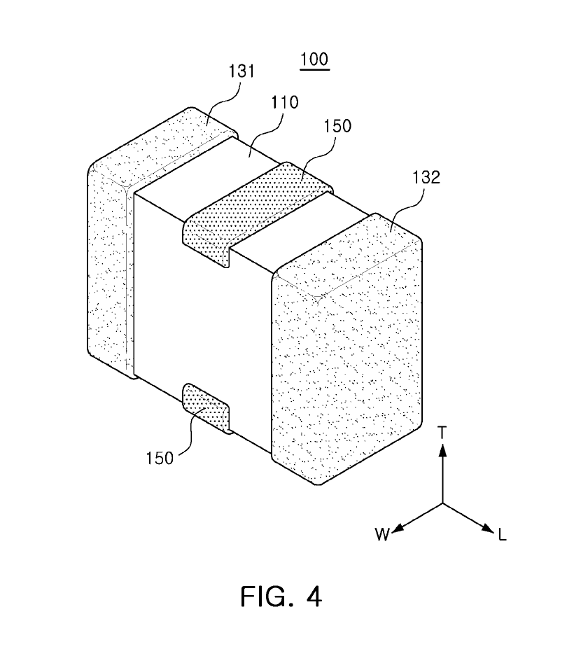

FIG. 4 is a perspective view schematically showing a modified example of the multilayer ceramic electronic component according to an exemplary embodiment of the present disclosure.

As shown in FIG. 4, in the modified example of the multilayer ceramic electronic component according to the exemplary embodiment of the present disclosure, the support portions 150 may be formed on the first and second main surfaces 5 and 6 of the ceramic body. In the case in which the support portions 150 are formed on both of the first and second main surfaces 5 and 6, any of the first and second main surfaces 5 and 6 of the ceramic body may be used as a mounting surface, and thus, it is not necessary to distinguish the first and second main surfaces 5 and 6 when the multilayer ceramic electronic component is mounted on the printed circuit board.

The support portion 150 may be formed of a paste used for forming the first and second external electrodes 131 and 132, but is not limited thereto.

The support portion 150 may contain tin (Sn) in order to improve adhesion with the dummy solder, but is not limited thereto. In the case in which the support portion does not contain tin (Sn), a Sn layer may be disposed on a surface of the support portion 150. The Sn layer may be formed by plating, but is not limited thereto.

The support portion 150 may be formed by applying the paste for forming the support portion to at least one of the first and second main surfaces 5 and 6 of the ceramic body and sintering or hardening the paste.

Alternatively, the support portion 150 may be formed through an intaglio printing process in which intaglios formed in rollers may be filled with the paste for forming the support portion and the ceramic body may be moved between the rollers to allow the paste accommodated in the intaglios of the rollers to be transferred to a surface of the ceramic body.

The forming of the support portion is not limited to the above-mentioned methods. That is, the method of forming the support portion is not particularly limited as long as it is appropriate for forming the support portion according to the exemplary embodiment of the present disclosure.

### Board Having Multilayer Ceramic Electronic Component

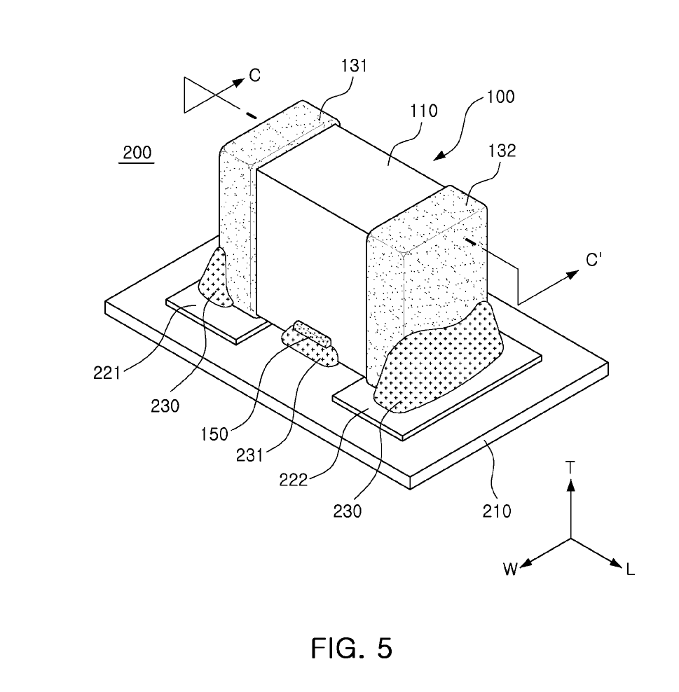

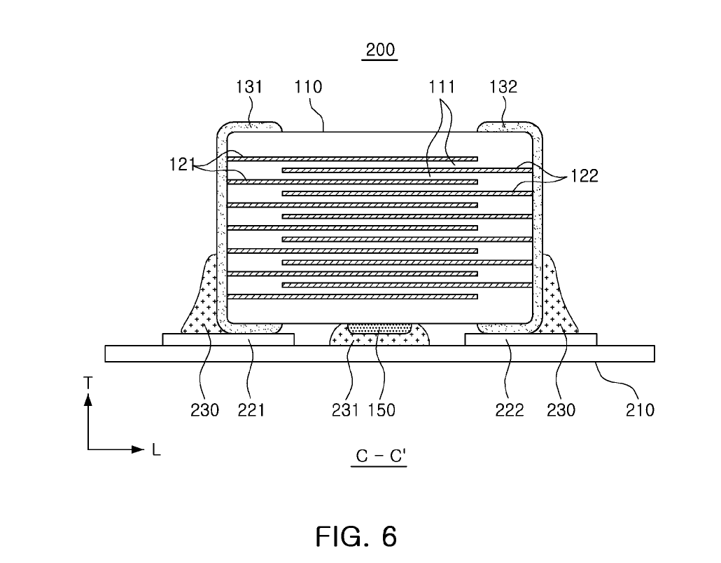

FIG. 5 is a perspective view showing a board 200 having a multilayer ceramic electronic component according to another exemplary embodiment of the present disclosure; and FIG. 6 is a cross-sectional view taken along line C-C′ of FIG. 5.

Referring to FIGS. 5 and 6, the board 200 having a multilayer ceramic electronic component according to another exemplary embodiment of the present disclosure may include a printed circuit board 210 including first and second electrode pads 221 and 222 disposed thereon to be spaced apart from each other, and a multilayer ceramic electronic component 100 mounted on the printed circuit board 210, and solder portions 230 and 231 connecting the multilayer ceramic electronic component and the printed circuit board to each other.

The multilayer ceramic electronic component 100 included in the board 200 according to the present exemplary embodiment is the same as the multilayer ceramic electronic component according to the above-described exemplary embodiment of the present disclosure. The multilayer ceramic electronic component 100 may include the ceramic body 110 having the first and second side surfaces opposing each other in the width direction, the third and fourth end surfaces opposing each other in the length direction, and the first and second main surfaces opposing each other in the thickness direction and having a thickness larger than a width, the internal electrodes 121 and 122 disposed in the ceramic body, the first and second external electrodes 131 and 132 disposed on the third and fourth end surfaces of the ceramic body, respectively, and the support portion 150 disposed on at least one of the first and second main surfaces.

A detailed description of the multilayer ceramic electronic component will be omitted in order to avoid redundancy.

The multilayer ceramic electronic component 100 may be electrically connected to the printed circuit board 210 by the solder portions 230 and 231 in a state in which the first and second external electrodes 131 and 132 are positioned on the first and second electrode pads 221 and 222, respectively.

The solder portions may include main solders 230 connected to the first and second external electrodes, and a dummy solder 231 that is not connected to the first and second external electrodes. The main solder 230 may electrically connect the multilayer ceramic electronic component 100 to the printed circuit board 210.

The dummy solder 231 may be disposed between the first and second electrode pads to be spaced apart from the first and second electrode pads 221 and 222.

The dummy solder 231 may be connected to the support portion 150 to decrease a mounting defect due to the displacement of the multilayer ceramic electronic component at the time of mounting the multilayer ceramic electronic component on the board.

A dummy solder paste may be applied to the support portion 150. Since the dummy solder paste has viscosity, it may allow the support portion 150 to be buried therein. Therefore, the portion of the support portion 150 may be buried in the dummy solder 231.

As set forth above, according to exemplary embodiments of the present disclosure, a multilayer ceramic electronic component and a board having the same may achieve improved mounting stability.

While exemplary embodiments have been shown and described above, it will be apparent to those skilled in the art that modifications and variations could be made without departing from the spirit and scope of the present disclosure as defined by the appended claims.

What is claimed is:

1. A multilayer ceramic electronic component, comprising:
a ceramic body having first and second side surfaces opposing each other in a width direction, first and second end surfaces opposing each other in a length direction, and first and second main surfaces opposing each other in a thickness direction, and having a thickness larger than a width;
internal electrodes disposed in the ceramic body;
first and second external electrodes disposed on the third and fourth end surfaces of the ceramic body, respectively; and
a support portion disposed on at least one of the first and second main surfaces and preventing displacement of the ceramic body at the time of being mounted on a board.

2. The multilayer ceramic electronic component of claim 1, wherein the support portion is electrically insulated from the internal electrodes.

3. The multilayer ceramic electronic component of claim 1, wherein the support portion is spaced apart from the first and second external electrodes.

4. The multilayer ceramic electronic component of claim 1, wherein the first and second external electrodes include band portions extended from the third and fourth end surfaces of the ceramic body to the first and second main surfaces of the ceramic body, and
when a width of the band portion is B1 and a width of the support portion is B2, 0.8≦B2/B1≦1.2 is satisfied.

5. The multilayer ceramic electronic component of claim 1, wherein the support portion includes extended portions extended from the at least one of the first and second main surfaces to the first and second side surfaces.

6. The multilayer ceramic electronic component of claim 1, wherein the support portion is formed on the first and second main surfaces of the ceramic body.

7. The multilayer ceramic electronic component of claim 1, wherein the support portion is formed by using an intaglio printing process.

8. A board having a multilayer ceramic electronic component, the board comprising:
a printed circuit board on which first and second electrode pads are disposed;
the multilayer ceramic electronic component disposed on the printed circuit board; and
a solder portion connecting the printed circuit board and the multilayer ceramic electronic component to each other,
wherein the multilayer ceramic electronic component includes:
a ceramic body having first and second side surfaces opposing each other in a width direction, third and fourth end surfaces opposing each other in a length direction, and first and second main surfaces opposing each other in a thickness direction and having a thickness larger than a width;
internal electrodes disposed in the ceramic body;
first and second external electrodes disposed on the third and fourth end surfaces of the ceramic body, respectively; and
a support portion disposed on at least one of the first and second main surfaces,
the first or second main surface of the ceramic body being disposed to be adjacent to and face the printed circuit board.

9. The board of claim 8, wherein the solder portion includes a dummy solder connected to the support portion.

10. The board of claim 9, wherein a portion of the support portion is buried in the dummy solder.

11. The board of claim 9, wherein the dummy solder is spaced apart from the first and second electrode pads.

12. The board of claim 8, wherein the support portion is electrically insulated from the internal electrodes.

13. The board of claim 8, wherein the support portion is spaced apart from the first and second external electrodes.

14. The board of claim 8, wherein the first and second external electrodes include band portions extended from the third and fourth end surfaces of the ceramic body to the first and second main surfaces of the ceramic body, and
when a width of the band portion is B1 and a width of the support portion is B2, 0.8≦B2/B1≦1.2 is satisfied.

15. The board of claim 8, wherein the support portion includes extended portions extended from at least one of the first and second main surfaces to the first and second side surfaces.
